(19) United States
(12) Patent Application Publication
(10) Pub. No.: US 2025/0204229 A1
(43) Pub. Date: Jun. 19, 2025

(54) DISPLAY APPARATUS AND MANUFACTURING METHOD THEREOF

(71) Applicants: Beijing Zitiao Network Technology Co., Ltd., Beijing (CN); Lemon Inc., Grand Cayman (KY)

(72) Inventors: Wenbin BAI, Beijing (CN); Ziyang ZHANG, Los Angeles, CA (US); Ling FU, Beijing (CN); Shuai DONG, Beijing (CN); Xing FAN, Beijing (CN); Yage SONG, Beijing (CN); Hsin-Yi HU, Beijing (CN)

(21) Appl. No.: 18/980,846

(22) Filed: Dec. 13, 2024

(30) Foreign Application Priority Data
Dec. 13, 2023 (CN) 202311709073.3

(51) Int. Cl. H10K 59/80; H10K 59/12

(52) U.S. Cl. CPC H10K 59/879; H10K 59/1201

(57) ABSTRACT

A display apparatus and a manufacturing method thereof are provided. The display apparatus includes a display panel and a lens structure. The display panel includes a substrate and a plurality of sub-pixels located on the substrate. The lens structure is located on a light-emitting side of the display panel, and a lens surface of the lens structure close to the display panel is a curved surface. The display panel includes a first region and a second region surrounding the first region, an included angle between a light-emitting surface of a sub-pixel located in the first region and an optical axis of the lens structure is greater than an included angle between a light-emitting surface of a sub-pixel located in the second region and the optical axis.

The present application claims priority to Chinese Patent Application No. 202311709073.3, filed on Dec. 13, 2023, the disclosure of which is incorporated herein in its entirety as part of the present application.

### TECHNICAL FIELD

The embodiments of the present disclosure relate to a display apparatus and a manufacturing method thereof.

### BACKGROUND

At present, liquid crystal displays (LCDs) are typically used as micro displays required for virtual reality head-mounted display devices. However, to meet the demand of users for high-definition displays, organic light-emitting diode (OLED) displays with higher pixel densities are used as micro displays. Although silicon-based OLEDs have advantages such as the high pixel density, high contrast, and wide color gamut, they also have problems such as small size.

In order to solve the matching problem between an optical module with a larger size and a display with a smaller size, a micro-lens array (MLA) can be introduced therebetween to match the chief ray angle (CRA) in the center of the entrance pupil of the optical module. In particular, using the MLA at a large field of view may significantly improve the light efficiency and ensure consistent brightness and chromaticity of images.

### SUMMARY

The embodiments of the present disclosure provide a display apparatus and a manufacturing method thereof.

An embodiment of the present disclosure provides a display apparatus, which includes: a display panel and a lens structure. The display panel includes a substrate and a plurality of sub-pixels located on the substrate; the lens structure located on a light-emitting side of the display panel, and a lens surface of the lens structure close to the display panel is a curved surface. The display panel includes a first region and a second region surrounding the first region, and an included angle between a light-emitting surface of a sub-pixel located in the first region and an optical axis of the lens structure is greater than an included angle between a light-emitting surface of a sub-pixel located in the second region and the optical axis.

For example, according to an embodiment of the present disclosure, a chief ray of the sub-pixel located in the first region is parallel to the optical axis of the lens structure, and an included angle between a chief ray of the sub-pixel located in the second region and the optical axis is greater than 0 degrees and less than or equal to 75 degrees.

For example, according to an embodiment of the present disclosure, the substrate includes a reference surface, and a distance between a center of the light-emitting surface of the sub-pixel in the first region and the reference surface is smaller than a distance between a center of the light-emitting surface of the sub-pixel in the second region and the reference surface.

For example, according to an embodiment of the present disclosure, minimum distances between the lens surface and centers of the light-emitting surfaces of the sub-pixels are 0.2 mm to 50 mm.

For example, according to an embodiment of the present disclosure, a radius of curvature of the lens surface is −300 mm to 300 mm.

For example, according to an embodiment of the present disclosure, a part of the substrate located in the second region is provided with an inclined groove, the inclined groove includes a groove bottom furthest away from the lens structure, and a distance between a center of the light-emitting surface of the sub-pixel located in the inclined groove and a plane parallel to a main surface of the substrate where the groove bottom is located is 20 nm to 50 mm.

For example, according to an embodiment of the present disclosure, a chief ray angle CRA1 of at least some sub-pixels in the display panel and a chief ray angle CRA0 of the lens structure satisfy a following relationship: CRA1={[tan⁻¹(H−Z)]/(f+e+T+CRA0)}+{[tan⁻¹(H/Z)]/(R−f−e−T−CRA0)}, where a part of the substrate located in the second region is provided with an inclined groove, the inclined groove includes a groove bottom furthest away from the lens structure, a distance between a center of the light-emitting surface of the sub-pixel located in the inclined groove and a plane parallel to a main surface of the substrate where the groove bottom is located is H, a distance between the lens surface and a display surface at a position of the sub-pixel is Z, f represents a focal length of the lens structure, e represents a size of an entrance pupil, T represents an included angle between the chief ray angle of the sub-pixel and the optical axis of the lens structure, and R represents a radius of curvature of the lens surface.

For example, according to an embodiment of the present disclosure, the lens surface is closer to the display panel at a center than at an edge, and in a direction from a center to an edge of the display panel, T values of multiple sub-pixels in the second region gradually increase.

For example, according to an embodiment of the present disclosure, the lens surface is closer to the display panel at a center than at an edge, and in a direction from a center to an edge of the display panel, H values of multiple sub-pixels in the second region gradually increase.

For example, according to an embodiment of the present disclosure, the second region includes a plurality of annular sub-regions, the first region includes a center of the display panel, and the plurality of annular sub-regions is provided sequentially along a direction from the center to the edge, and for different sub-pixels in the same annular sub-region, T values are the same, and H values are the same.

For example, according to an embodiment of the present disclosure, in the direction from the center to the edge, for the sub-pixels in different annular sub-regions, T values gradually increase, and H values gradually increase.

For example, according to an embodiment of the present disclosure, an incident angle of a chief ray of light emitted from the light-emitting surface of the sub-pixel in the second region that is incident on the lens surface is not greater than 5 degrees.

For example, according to an embodiment of the present disclosure, the plurality of sub-pixels includes a red sub-pixel, a green sub-pixel, and a blue sub-pixel.

For example, according to an embodiment of the present disclosure, the lens surface includes a spherical surface, an aspherical surface, or a freeform curved surface.

For example, according to an embodiment of the present disclosure, each sub-pixel includes a light-emitting diode or an organic light-emitting diode.

For example, according to an embodiment of the present disclosure, the inclined groove includes an inclined main surface, the sub-pixel includes a light-emitting layer, and the light-emitting layer is arranged on the inclined main surface.

Another embodiment of the present disclosure provides a method for manufacturing a display apparatus, which includes: forming a display panel, wherein the display panel includes a substrate and a plurality of sub-pixels located on the substrate; providing a lens structure on a light-emitting side of the display panel, wherein a lens surface of the lens structure close to the display panel is a curved surface. The display panel includes a first region and a second region surrounding the first region, and forming the display panel includes: forming a plurality of inclined grooves on a side of the substrate in the second region facing the lens structure; and forming the sub-pixels in the inclined grooves such that an included angle between a light-emitting surface of a sub-pixel located in the first region and an optical axis of the lens structure is greater than an included angle between a light-emitting surface of a sub-pixel located in the second region and the optical axis.

### BRIEF DESCRIPTION OF DRAWINGS

In order to more clearly illustrate the technical solutions of the embodiments of the present disclosure, the accompanying drawings of the embodiments will be briefly introduced below, it is obvious that the accompanying drawings in the following description merely relate to some embodiments of the present disclosure, but not the limitations of the present disclosure.

FIG. 1 is a structural schematic diagram of a display apparatus according to an embodiment of the present disclosure.

FIG. 2 is a schematic diagram of a part cross-sectional structure of the display panel shown in FIG. 1.

FIG. 3 is a schematic diagram of a partial plane structure of the display panel shown in FIG. 1 in an example.

FIG. 4 is a schematic diagram of tilt angles of sub-pixels in different regions shown in FIG. 3.

FIG. 5 is a schematic diagram of sub-pixels in a local region of the display panel of the display apparatus shown in FIG. 1.

FIG. 6 is a schematic diagram of a partial plane structure of the display panel shown in FIG. 1 in another example.

FIG. 7 is a schematic diagram of a part cross-sectional structure of the display apparatus provided in an example according to an embodiment of the present disclosure.

FIG. 8 to FIG. 10 are partial process flow charts of a manufacturing method of a display panel in a display device provided according to an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects.

The features “parallel”, “perpendicular” and “same” used in the embodiments of the present disclosure all include features such as “parallel”, “perpendicular” and “same” in the strict sense, and the cases having certain errors, such as “approximately parallel”, “approximately perpendicular”, “approximately the same” or the like, taking into account measurements and errors associated with the measurement of a particular quantity (e.g., limitations of the measurement system), and indicate being within an acceptable range of deviation for a particular value as determined by one of ordinary skill in the art. For example, “approximately” may indicate being within one or more standard deviations, or within 10% or 5% of the stated value. In the case that the quantity of a component is not specifically indicated below in the embodiments of the present disclosure, it means that the component may be one or more, or may be understood as at least one. “At least one” means one or more, and “plurality” means at least two.

In the study, the inventor of the present application found that in order to solve the matching problem between an optical module with a larger size and a display screen with a smaller size, a microlens array (MLA) may be introduced therebetween. There are many imperfections in the design and the arrangement of the MLA. For example, at a different entrance pupil position, even with the MLA technology, it may not be able to fully match the different CRA values at different positions of the optical module, which may cause inconsistent brightness and chromaticity at the edge of the image and at the center of the image when the user is viewing the screen, resulting in adverse reactions such as visual fatigue, dizziness, or discomfort. For example, display screens of different display devices have different parameters such as pixel arrangement, so it is necessary to adjust the MLA accordingly according to the pixel parameters in the display screens to achieve the best CRA compensation effect. For example, matching the MLA to the CRA of the display screen may lead to inconsistencies in the color and brightness of the image, which may cause color deviation or distortion of the displayed image, which will affect the viewing experience of users. For example, because it is not possible to fully match the MLA to the CRA of the display screen, the size or the like of the display screen may be limited, and some models of display screens may not be compatible with a specific MLA, which may lead to a limited selection.

The embodiments of the present disclosure provide a display apparatus and a manufacturing method thereof. The display apparatus includes a display panel and a lens structure. The display panel includes a substrate and a plurality of sub-pixels located on the substrate. The lens structure is located on a light-emitting side of the display panel, and a lens surface of the lens structure close to the display panel is a curved surface. The display panel includes a first region and a second region surrounding the first region, an included angle between a light-emitting surface of a sub-pixel located in the first region and an optical axis of the lens structure is greater than an included angle between a light-emitting surface of a sub-pixel located in the second region and the optical axis. The display apparatus provided by the present disclosure can match the chief ray angle of sub-pixels in the display panel to the chief ray angle of the lens structure by adjusting the included angle between the light-emitting surface of sub-pixels located in different regions of the display panel and the optical axis of the lens structure, increasing flexibility in the optical imaging design, improving the quality of the displayed image, improving the uniformity of display brightness or chromaticity, reducing stray light, and improving contrast.

The display apparatus and the manufacturing method thereof provided in the present disclosure are described below with reference to the accompanying drawings.

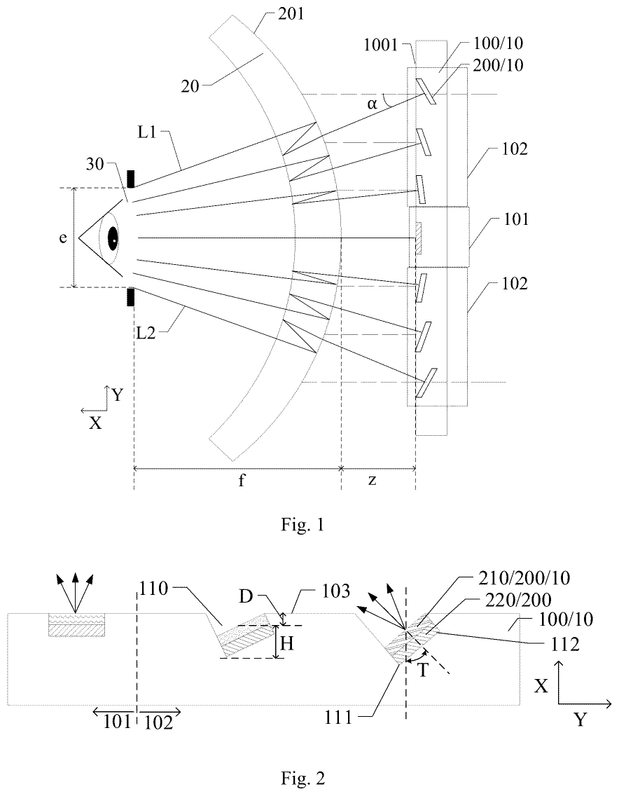

FIG. 1 is a structural schematic diagram of a display apparatus according to an embodiment of the present disclosure. FIG. 2 is a schematic diagram of a part cross-sectional structure of the display panel shown in FIG. 1.

As shown in FIG. 1 and FIG. 2, the display apparatus includes a display panel 10 and a lens structure 20. The display panel 10 includes a substrate 100 and a plurality of sub-pixels 200 located on the substrate 100. The lens structure 20 is located on a light-emitting side of the display panel 10, and a lens surface 201 of the lens structure 20 close to the display panel 10 is a curved surface 201. For example, light rays emitted from the display panel 10 pass through the lens structure 20 and are directed to the entrance pupil 30. For example, the lens surface 201 of the lens structure 20, such as the curved surface 201, may be a surface on a light-incident side of the lens structure 20. For example, the lens surface 201 may be a first surface of the lens structure 20, and the lens structure 20 may also include another surface, such as a second surface.

As shown in FIG. 1 and FIG. 2, the display panel 10 includes a first region 101 and a second region 102 surrounding the first region 101, the included angle of a light-emitting surface of sub-pixels 200 located in the first region 101 relative to an optical axis of the lens structure 20 is greater than the included angle of a light-emitting surface of sub-pixels 200 located in the second region 102 relative to the optical axis of the lens structure 20. For example, the optical axis of the lens structure 20 is parallel to the direction X. The included angle of the light-emitting surface relative to the optical axis refers to an included angle not greater than 90 degrees.

Compared to a display apparatus in which a microlens array (MLA) is provided between a general display panel and a lens structure to match the chief ray angle of the lens structure, the display apparatus provided by the present disclosure can match the chief ray angle of sub-pixels 200 in the display panel 10 to the chief ray angle of the lens structure 20 by adjusting the included angle of the light-emitting surface of sub-pixels 200 located in different regions of the display panel 10 relative to the optical axis of the lens structure 20, increasing flexibility in the optical imaging design, improving the quality of the displayed image, improving the uniformity of display brightness or chromaticity, reducing stray light, and improving contrast.

For example, as shown in FIG. 1, by adjusting the included angle of the light-emitting surface of sub-pixels 200 at different positions in the display panel 10 relative to the optical axis of the lens structure 20, the lens structure 20 may be more flexibly matched to the display panel 10, improving design freedom of the combination of the optical structure and the display panel 10 for imaging.

For example, as shown in FIG. 1, the display panel 10 includes a display surface 1001, such as a display screen, at the light-emitting side of the plurality of sub-pixels 200, and the optical axis of the lens structure 20 is perpendicular to the display surface 1001. For example, the display surface 1001 can be a plane perpendicular to the direction X shown in FIG. 1. For example, the included angle of the light-emitting surface of the sub-pixels 200 located in the first region 101 relative to the display plane 1001 is smaller than the included angle of the light-emitting surface of the sub-pixels 200 located in the second region 102 relative to the display surface 1001.

In the display apparatus provided in the present disclosure, the light-emitting surfaces of the sub-pixels 200 in different regions are tilted at different angles relative to the display surface 1001, such that the chief ray angel CRA1 of the sub-pixels 200 at different positions of the display panel 10 may be better adjusted so as to match the chief ray angles CRA0 of the lens structure 20 at the corresponding position where the light emitted from the sub-pixels 200 at different positions enters the lens structure 20.

In some examples, as shown in FIG. 1, an angle of incidence of the chief light rays in the light rays emitted from the light-emitting surface of the sub-pixels 200 in the second region 102 incident on the lens surface 201 of the lens structure 20, such as the curved surface 201, is not greater than 5 degrees. For example, the angle of incidence of the chief light rays in the light rays emitted from the light-emitting surface of the sub-pixels 200 in the second region 102 incident on the curved surface 201 of the lens structure 20 is not greater than 3 degrees. For example, the angle of incidence of the chief light rays in the light rays emitted from the light-emitting surface of the sub-pixels 200 in the second region 102 incident on the curved surface 201 of the lens structure 20 is not greater than 2 degrees. For example, the angle of incidence of the chief light rays in the light rays emitted from the light-emitting surface of the sub-pixels 200 in the second region 102 incident on the curved surface 201 of the lens structure 20 is not greater than 1 degree. For example, the angle of incidence of the chief light rays in the light rays emitted from the light-emitting surface of the sub-pixels 200 in the first region 101 incident on the curved surface 201 of the lens structure 20 is 0 degrees. For example, the chief light rays in the light rays emitted from the light-emitting surface of the sub-pixels 200 in the second region 102 are incident on the curved surface 201 of the lens structure 20 at a substantially perpendicular angle. The above substantially perpendicular angle may indicate that the included angle of the emergent light that is incident on the curved surface relative to the tangent line of curved surface may be 88 degrees to 92 degrees, such as 89 degrees to 91 degrees, such as 90 degrees.

For example, as shown in FIG. 1, the light-emitting surfaces of the sub-pixels 200 located in the second region 102 are inclined towards the first region 101. For example, the chief rays in the light rays emitted from the light-emitting surface of the sub-pixels 200 in the second region 102 are deflected to the side close to the optical axis of the lens structure 20.

By providing the light-emitting surfaces of the sub-pixels 200 in different regions as tilted relative to the display surface 1001 at different angles, the angle of incidence of the chief rays from the sub-pixels 200 in different regions that are incident on the lens surface 201 of the lens structure 20, such as the curved surface 201, is adjusted be 0 degrees or close to 0 degrees, thereby matching the chief ray angles CRA1 of different sub-pixels 200 of the display panel 10 to different chief ray angles CRA0 at different positions of the lens structure 20.

In some examples, as shown in FIG. 1, the chief rays of the sub-pixel 200 located in the first region 101 are parallel to the optical axis of the lens structure 20, and the included angle of the chief ray of the sub-pixel 200 located in the second region 102 relative to the optical axis is greater than 0 degrees and less than or equal to 75 degrees. For example, the chief ray of the sub-pixel 200 in the first region 101 is perpendicular to the display surface 1001. For example, the included angle of the chief ray of the sub-pixel 200 in the second region 102 relative to the normal line perpendicular to the display surface 1001 is greater than 0 degrees and less than or equal to 75 degrees. For example, the optical axis of the lens structure 20 passes through the first region 101 of the display panel 10.

For example, as shown in FIG. 1, the included angle of the chief ray of the sub-pixel 200 located in the second region 102 relative to the optical axis is 5 degrees to 70 degrees. For example, the included angle of the chief ray of the sub-pixel 200 located in the second region 102 relative to the optical axis is 2 degrees to 30 degrees. For example, the included angle of the chief rays of the sub-pixels 200 located in the second region 102 relative to the optical axis is 1 degree to 20 degrees. For example, the included angle of the chief ray of the sub-pixel 200 located in the second region 102 relative to the optical axis is 10 degrees to 45 degrees. For example, the included angle of the chief ray of the sub-pixel 200 located in the second region 102 relative to the optical axis is 15 degrees to 60 degrees. For example, the included angle of the chief ray of the sub-pixel 200 located in the second region 102 relative to the optical axis is 12 degrees to 40 degrees. For example, the included angle of the chief ray of the sub-pixel 200 located in the second region 102 relative to the optical axis is 35 degrees to 50 degrees.

For example, as shown in FIG. 1, the included angle of the light-emitting surface of the sub-pixels 200 in the second region 102 relative to the display surface 1001 is greater than 0 degrees and less than or equal to 75 degrees. For example, the included angle of the light-emitting surface of the sub-pixels 200 located in the second region 102 relative to the display surface 1001 is 5 degrees to 70 degrees. For example, the included angle of the light-emitting surface of the sub-pixels 200 located in the second region 102 relative to the display surface 1001 is 2 degrees to 30 degrees. For example, the included angle of the light-emitting surface of the sub-pixels 200 located in the second region 102 relative to the display surface 1001 is 1 degree to 20 degrees. For example, the included angle of the light-emitting surface of the sub-pixels 200 located in the second region 102 relative to the display surface 1001 is 10 degrees to 45 degrees. For example, the included angle of the light-emitting surface of the sub-pixels 200 located in the second region 102 relative to the display surface 1001 is 15 degrees to 60 degrees. For example, the included angle of the light-emitting surface of the sub-pixels 200 located in the second region 102 relative to the display surface 1001 is 12 degrees to 40 degrees. For example, the included angle of the light-emitting surface of the sub-pixels 200 located in the second region 102 relative to the display surface 1001 is 35 degrees to 50 degrees. For example, the included angle of the light-emitting surface of the sub-pixels 200 located in the second region 102 relative to the display surface 1001 is 1 degree to 74 degrees. For example, the included angle of the light-emitting surface of the sub-pixels 200 located in the second region 102 relative to the display surface 1001 is 3 degrees to 73 degrees. For example, the included angle of the light-emitting surface of the sub-pixels 200 located in the second region 102 relative to the display surface 1001 is 6 degrees to 66 degrees. For example, the included angle of the light-emitting surface of the sub-pixels 200 located in the second region 102 relative to the display surface 1001 is 7 degrees to 55 degrees.

By adjusting the inclination angle of the light-emitting surface of the sub-pixels 200 in the second region 102 relative to the display surface 1001 to adjust the included angle of the chief rays of the sub-pixels 200 in the second region 102 relative to the optical axis of the lens structure 20, It is beneficial to achieving the matching effect between the CRA1 of the sub-pixel 200 and the CRA0 of the lens structure 20.

In some examples, as shown in FIG. 2, the substrate 100 includes a reference surface 103, and the distance between the center of the light-emitting surface of the sub-pixels 200 in the first region 101 and the reference surface 103 is smaller than the distance D between the center of the light-emitting surface of the sub-pixels 200 in the second region 102 and the reference surface 103. FIG. 2 schematically shows that the center of the light-emitting surface of the sub-pixels 200 in the first region 101 is flush with the reference surface 103, but is not limited to this, and the distance between the center of the light-emitting surface of the sub-pixels 200 in the first region 101 and the reference surface 103 of the substrate 100 can be set according to the product requirements.

For example, as shown in FIG. 1 and FIG. 2, the distance between the center of the light-emitting surface of the sub-pixels 200 in the first region 101 and the display surface 1001 is smaller than the distance between the center of the light-emitting surface of the sub-pixels 200 in the second region 102 and the display surface 1001. For example, the larger the included angle between the light-emitting surface of the sub-pixels 200 and the display plane 1001, the greater the distance between the center of the light-emitting surface of the sub-pixels 200 and the display plane 1001.

For example, as shown in FIG. 2, the reference surface 103 of the substrate 100 may be a surface with an opening in which at least a partial layer of the sub-pixels 200 is provided.

In some examples, as shown in FIG. 1, the minimum distance Z between the lens surface 201 of the lens structure 20, such as the curved surface 201, and the center of the light-emitting surface of the sub-pixels 200 of the display panel 10 is 0.2 mm to 50 mm. For example, the minimum distance Z between the curved surface 201 of the lens structure 20 and the center of the light-emitting surface of the sub-pixels 200 of the display panel 10 is 0.23 mm to 45 mm. For example, the minimum distance Z between the curved surface 201 of the lens structure 20 and the center of the light-emitting surface of the sub-pixels 200 of the display panel 10 is 0.25 mm to 40 mm. For example, the minimum distance Z between the curved surface 201 of the lens structure 20 and the center of the light-emitting surface of the sub-pixels 200 of the display panel 10 is 0.27 mm to 35 mm. For example, the minimum distance Z between the curved surface 201 of the lens structure 20 and the center of the light-emitting surface of the sub-pixels 200 of the display panel 10 is 0.28 mm to 30 mm. For example, the minimum distance Z between the curved surface 201 of the lens structure 20 and the center of the light-emitting surface of the sub-pixels 200 of the display panel 10 is 0.2 mm to 5 mm. For example, the minimum distance Z between the curved surface 201 of the lens structure 20 and the center of the light-emitting surface of the sub-pixels 200 of the display panel 10 may be 0.5 mm to 3 mm. For example, the minimum distance Z between the curved surface 201 of the lens structure 20 and the center of the light-emitting surface of the sub-pixels 200 of the display panel 10 may be 0.3 mm to 4 mm. For example, the minimum distance Z between the curved surface 201 of the lens structure 20 and the center of the light-emitting surface of the sub-pixels 200 of the display panel 10 may be 0.4 mm to 3.5 mm. For example, the minimum distance Z between the curved surface 201 of the lens structure 20 and the center of the light-emitting surface of the sub-pixels 200 of the display panel 10 may be 0.8 mm to 2 mm. For example, the minimum distance Z between the curved surface 201 of the lens structure 20 and the center of the light-emitting surface of the sub-pixels 200 of the display panel 10 may be 1 mm to 4.5 mm. For example, the minimum distance Z between the curved surface 201 of the lens structure 20 and the center of the light-emitting surface of the sub-pixels 200 of the display panel 10 may be 1.5 mm to 2.5 mm. For example, the minimum distance Z between the curved surface 201 of the lens structure 20 and the center of the light-emitting surface of the sub-pixels 200 of the display panel 10 may be 0.35 mm to 4.8 mm. For example, the minimum distance Z between the curved surface 201 of the lens structure 20 and the center of the light-emitting surface of the sub-pixels 200 of the display panel 10 may be 1.2 mm to 3.7 mm.

In some examples, as shown in FIG. 1, the radius of curvature R of the lens surface 201 of the lens structure 20, such as the curved surface 201, is −300 mm to 300 mm.

For example, as shown in FIG. 1, the lens surface 201 of the lens structure 20, such as the curved surface 201, is closer to the display panel 10 at the center than at the edge. For example, the radius of curvature R of the curved surface 201 of the lens structure 20 is −280 mm to −1 mm. For example, the radius of curvature R of the curved surface 201 of the lens structure 20 is −250 mm to −100 mm. For example, the radius of curvature R of the curved surface 201 of the lens structure 20 is −240 mm to −20 mm. For example, the radius of curvature R of the curved surface 201 of the lens structure 20 is −200 mm to −50 mm. For example, the radius of curvature R of the curved surface 201 of the lens structure 20 is −220 mm to −80 mm. For example, the radius of curvature R of the curved surface 201 of the lens structure 20 is −180 mm to −10 mm. For example, the radius of curvature R of the curved surface 201 of the lens structure 20 is −170 mm to −45 mm. For example, the radius of curvature R of the curved surface 201 of the lens structure 20 is −120 mm to −15 mm. For example, the radius of curvature R of the curved surface 201 of the lens structure 20 is −100 mm to −30 mm. For example, the radius of curvature R of the curved surface 201 of the lens structure 20 is −150 mm to −60 mm. For example, the radius of curvature R of the curved surface 201 of the lens structure 20 is −90 mm to −40 mm. For example, the curved surface 201 of the lens structure 20 is farther away from the display panel 10 at the center than at the edge. For example, the radius of curvature R of the curved surface 201 of the lens structure 20 is 10 mm to 200 mm. For example, the radius of curvature R of the curved surface 201 of the lens structure 20 is 20 mm to 100 mm. For example, the radius of curvature R of the curved surface 201 of the lens structure 20 is 50 mm to 150 mm. For example, the radius of curvature R of the curved surface 201 of the lens structure 20 is 80 mm to 250 mm. For example, the radius of curvature R of the curved surface 201 of the lens structure 20 is 45 mm to 220 mm. For example, the radius of curvature R of the curved surface 201 of the lens structure 20 is 60 mm to 270 mm. For example, the radius of curvature R of the curved surface 201 of the lens structure 20 is 120 mm to 180 mm. For example, the radius of curvature R of the curved surface 201 of the lens structure 20 is 140 mm to 240 mm.

In some examples, as shown in FIG. 1, the lens surface 201 of the lens structure 20, such as the curved surface 201, includes a spherical surface, an aspherical surface, or a freeform curved surface. FIG. 1 schematically shows that the lens structure 20 is a single lens, but is not limited to this, and the lens structure 20 may also include two or more lenses.

The display apparatus provided in the present disclosure may dispose the inclination angle of the light-emitting surface of the sub-pixels 200 in different regions, the minimum distance between the center of the light-emitting surface of the sub-pixels 200 in different regions and the lens surface 201 of the lens structure 20, and the curvature of the lens surface 201 of the lens structure 20, so as to improve the matching effect between the CRA1 of the sub-pixels 200 and the CRA0 of the lens structure 20, while ensuring that the light rays emitted from the light-emitting surface of the display panel 10 can be incident on the position of the entrance pupil 30 with a large field of view after substantially passing through the lens structure 20.

In some examples, as shown in FIG. 2, the part of the substrate 100 located in the second region 102 is provided with an inclined groove 110, the inclined groove 110 includes a groove bottom 111 furthest away from the lens structure 20, and the distance H between the center of the light-emitting surface of sub-pixels 200 located in the inclined groove 110 and the plane parallel to the main surface of the substrate 100 where the groove bottom 111 is located is 20 nanometers to 50 microns. For example, the sub-pixels 200 located in the second region 102 are all located in the inclined grooves 110 of the substrate 100. Of course, the embodiments of the present disclosure are not limited to this, and a part of the film layer in the sub-pixels located in the second region may be located in the inclined groove, and the other part of the film layer is located outside the inclined groove.

For example, the distance H may be 20 nm to 50 μm. For example, the distance H may be 30 nm to 100 nm. For example, the distance H may be 50 nm to 1 μm. For example, the distance H may be 60 nm to 500 nm. For example, the distance H may be 150 nm to 300 nm. For example, the distance H may be 200 nm to 800 nm. For example, the distance H may be 5 μm to 30 μm. For example, the distance H may be 10 μm to 20 μm. For example, the distance H may be 7 μm to 40 μm. For example, the distance H may be 22 nm to 48 μm. For example, the distance H may be 25 nm to 45 μm.

For example, as shown in FIG. 2, the smaller the included angle of the light-emitting surface of the sub-pixels 200 relative to the optical axis of the lens structure 20, the larger the included angle T of the chief rays of the light rays emitted from the sub-pixels 200 relative to the optical axis, and the greater the distance H between the center of the light-emitting surface of the sub-pixels 200 and the plane parallel to the main surface of the substrate 100 where the bottom of the groove 111 is located.

In some examples, as shown in FIG. 2, the inclined groove 110 includes an inclined main surface 112, the sub-pixels 200 include a light-emitting layer 210, and the light-emitting layer 210 is arranged on the inclined main surface 112. For example, the inclined main surface 112 is oriented towards the first region 101 such that the light-emitting surface of the sub-pixels 200 is inclined towards the side of the first region 101. For example, the light-emitting layer 210 is located entirely within the inclined groove 110. FIG. 2 schematically shows that the inclined main surface 112 is a plane, but is not limited to this, and the inclined main surface 112 may be a curved surface or a wave-shaped surface or other surface types, and can be designed according to product requirements.

For example, as shown in FIG. 2, the substrate 100 may refer to a base substrate, such as a glass substrate or a circuit substrate, and the side of the base substrate facing the lens structure 20 is provided with the above-mentioned inclined groove 110. For example, the substrate 100 may also refer to the base substrate and other film layers, such as an insulating layer, and the inclined groove 110 may be provided in other film layers arranged on the base substrate.

In some examples, as shown in FIG. 1 and FIG. 2, each sub-pixel 200 includes either a light-emitting diode (LED) or an organic light-emitting diode (OLED).

For example, as shown in FIG. 2, an electrode layer 220 is provided between the light-emitting layer 210 and the substrate 100, and the electrode layer 220 is configured to be electrified to drive the light-emitting layer 210 to emit light. For example, the sub-pixel 200 may be an organic light-emitting diode, the light-emitting layer 210 may include an organic light-emitting material, and a transparent electrode layer is provided on one side of the light-emitting layer 210 away from the substrate 100, such as a whole-surface transparent electrode layer 220 shared by multiple sub-pixels 200. For example, the transparent electrode layer may include a portion filled in the inclined groove 110 and a portion located between adjacent inclined grooves 110. For example, each sub-pixel 200 further includes a pixel circuit, such as a plurality of thin-film transistors and at least one capacitor, and the electrode layers on both sides of the light-emitting layer 210 are electrically connected with the pixel circuit to drive the light-emitting layer 210 to emit light. Of course, other functional layers may also be provided between the light-emitting layer 210 and the electrode layers on both sides thereof, such as an electron transport layer, a hole transport layer and other film layers. For example, the sub-pixels 200 may be a light-emitting diode, the light-emitting layer 210 may be a single quantum well (SQW) light-emitting layer 210, a multiple quantum well (MQW) light-emitting layer 210 or a quantum dot light-emitting layer 210, and a light-transmitting electrode layer 220 may be arranged on the side of the light-emitting layer 210 away from the substrate 100.

The sub-pixels 200 provided in at least some embodiments of the present disclosure may be a self-luminous structure, the self-luminous structure includes a light-emitting layer 210 for emitting light, and the light-emitting surface of the sub-pixels 200 may include a surface of the light-emitting layer 210 facing the lens structure 20.

In some examples, as shown in FIG. 1 and FIG. 2, the chief ray angle CRA1 of at least some sub-pixels 200 in the display panel 10 and the chief ray angle CRA0 of the lens structure 20 satisfy the following relationship (1):

$$CRA 1 = \{ [ {tan}^{- 1} ( H - Z ) ] / ( f + e + T + CRA 0 ) \} + \{ [ {tan}^{- 1} ( H / Z ) ] / ( R - f - e - T - CRA 0 ) \} .$$

The distance between the center of the light-emitting surface of the sub-pixels 200 located in the inclined groove 110 and the plane parallel to the main surface of the substrate 100 where the groove bottom 111 is located is H, the distance between the lens surface 201 of the lens structure 20, such as the curved surface 201, and the center of the light-emitting surface of the sub-pixels 200 is Z, f represents the focal length of the lens structure 20, e represents the size of the entrance pupil 30, T represents the included angle between the chief ray angle of the sub-pixels 200 and the optical axis of the lens structure 20, and R represents the radius of curvature of the lens surface 201 of the lens structure 20, such as the curved surface 201 The main surface of the substrate 100 may be a surface perpendicular to the direction X, such as a surface away from the lens structure 20. For example, H may represent the height of the light-emitting surface of the sub-pixels 200, T may represent the deflection angle of the chief rays of the sub-pixels 200 or the inclination angle of the light-emitting surface, and Z may represent the distance between the lens surface 201 of the lens structure 20, such as the curved surface 201, and the sub-pixels 200.

In some examples, as shown in FIG. 1 and FIG. 2, the plurality of sub-pixels 200 includes sub-pixels 200 of different colors, such as red sub-pixels, green sub-pixels, and blue sub-pixels. For example, a plurality of sub-pixels 200 in the second region 102 includes sub-pixels of different colors. For example, the sub-pixels 200 in the first region 101 may include sub-pixels of different colors, or may include only sub-pixels of the same color, for example, the first region 101 includes only one sub-pixel. For example, the chief ray angle CRA1 of sub-pixels of different colors and the chief ray angle CRA0 of the lens structure 20 satisfy the above relationship (1). For example, the chief rays of different sub-pixels 200 are incident on different positions of the lens surface 201 of the lens structure 20, such as the curved surface 201, the chief ray angles CRA1 of different sub-pixels 200 can correspond to the chief ray angles CRA0 at different positions of the lens structure 20.

For example, as shown in FIG. 1 and FIG. 2, the display apparatus may be a virtual reality (VR) display apparatus. For example, the size e of the entrance pupil of the display apparatus refers to the size of the pupil on the human eye side in the optical module, such as the lens structure 20. For example, the position of the entrance pupil 30 may be determined by the focal length f of the lens structure 20. The size and position of the entrance pupil 30 are closely related to the matching of the chief ray angle CRA1 of the sub-pixels 200 and the chief ray angle CRA0 of the lens structure 20, and the size and position of the entrance pupil 30 affect the imaging optical performance of the lens structure 20 and the refraction position of the chief rays in the light rays emitted from the sub-pixels 200. Therefore, when calculating the value of the chief ray angle CRA1 of the sub-pixels 200, it is necessary to consider the influence of the size and position of the entrance pupil 30. For example, the position of the entrance pupil 30 affects the refraction angle of the chief rays in the emergent light of the sub-pixels 200. For example, the smaller the distance between the entrance pupil 30 and the lens structure 20, the smaller the refraction angle of the chief rays from the sub-pixels 200 through the lens structure 20. For example, the size of the entrance pupil 30 determines the position of the most edge of the light rays at the position of the entrance pupil 30. As shown in FIG. 1, at the positions of the two edges of light rays L1 and L2 in the direction Y, the larger the entrance pupil 30, the larger the included angle between the edge rays, and the larger the refraction angle of the emergent light rays of the corresponding sub-pixels 200, which may cause chromatic aberration, so it is necessary to minimize the included angle between the edge rays. Of course, the display apparatus provided in the embodiments of the present disclosure is not limited to a virtual reality product, and may be other display apparatuses provided with a lens structure and a display panel.

For example, as shown in FIG. 1 and FIG. 2, referring to the above relationship (1), the height H of the sub-pixels 200, the distance Z between the sub-pixels 200 and the lens structure 20, and the deflection angle T of the chief rays of the sub-pixels 200 may be adjusted according to the CRA0 of the lens structure 20, the focal length f of the lens structure 20, the radius of curvature R of the lens surface 201 of the lens structure 201, such as the curved surface 201, and the size e of the entrance pupil 30, so as to obtain the best matching effect of CRA.

In the display apparatus provided in the present disclosure, by disposing the distance between the sub-pixels 200 at different positions and the lens structure 20, the height of the sub-pixels 200 and the deflection angle of the chief rays to match the CRA1 of the sub-pixels 200 at different positions and the CRA0 at the corresponding positions of the lens structure 20, the refraction angle of the chief rays of the sub-pixels 200 of different colors that are incident on the entrance pupil 30 after passing through the lens structure 20 is adjusted, thereby alleviating the problems of color shift and chromatic aberration generated by the display apparatus, which achieves a better color restoration effect and minimizes chromatic aberration.

In the display apparatus provided in the present disclosure, the chief rays of the sub-pixels 200 at the edge positions of the display panel 10 are adjusted to deflect towards being closer to the optical axis of the lens structure 20, which reduces edge stray light, and improves the contrast of the display apparatus, the brightness and chromaticity uniformity of the display apparatus.

FIG. 2 schematically shows that the substrate 100 in the first region 101 is provided with a groove, the main groove surface of the groove is perpendicular to the optical axis of the lens structure 20, and the groove is not an inclined groove. However, it is not limited to this, the substrate 100 in the first region 101 may also be provided without grooves, and film layers such as the light-emitting layer 210 of the sub-pixels 200 may be directly formed on the surface of the substrate 100.

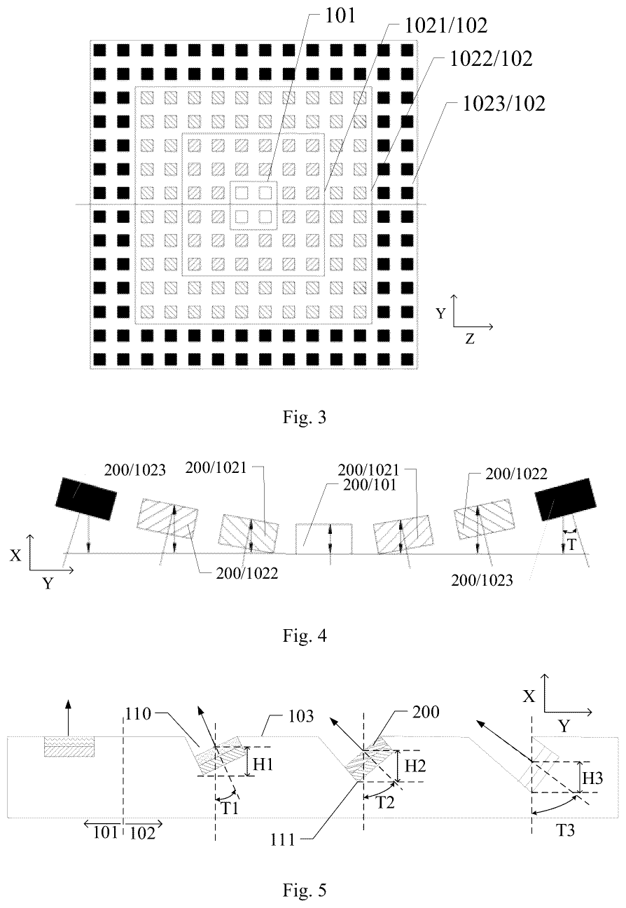

FIG. 3 is a schematic diagram of a partial plane structure of the display panel shown in FIG. 1 in an example. FIG. 4 is a schematic diagram of the tilt angles of sub-pixels in different regions shown in FIG. 3.

In some examples, as shown in FIG. 3 and FIG. 4, the second region 102 includes a plurality of annular sub-regions, the first region 101 includes the center of the display panel 10, and the plurality of annular sub-regions is provided sequentially along the direction from the center to the edge, and for different sub-pixels 200 in the same annular sub-region, the T values are the same, and the H values are the same. FIG. 4 schematically shows one sub-pixel 200 in the first region 101 and two sub-pixels 200 in each annular sub-region of the second region 102. FIG. 4 schematically shows the inclination angles of the sub-pixels 200 in each annular sub-region of the second region 102, and does not show the height, and the height variation thereof may refer to the height variation of the sub-pixels 200 in the second region 102 in FIG. 2.

For example, as shown in FIG. 3 and FIG. 4, the second region 102 may include three annular sub-regions 1021, 1022, and 1023, and each annular sub-region includes two rings of pixels 200, with the annular sub-region 1021 surrounding the first region 101, the annular sub-region 1022 surrounding the annular sub-region 1021, and the annular sub-region 1023 surrounding the annular sub-region 1022. For example, the height and the deflection angle of the chief ray of each sub-pixel 200 in the annular sub-region 1021 are the same. For example, the height and the deflection angle of the chief ray of each sub-pixel 200 in the annular sub-region 1022 are the same. For example, the height and the deflection angle of the chief ray of each sub-pixel 200 in the annular sub-region 1023 are the same. Of course, the embodiments of the present disclosure are not limited to that the second region 102 includes three annular sub-regions, nor is it limited to that the sub-pixels 200 in each annular sub-region are arranged into two concentric rings, which can be arranged according to the product requirements. The embodiments of the present disclosure are not limited to that there are four sub-pixels 200 in the first region 101. For example, there are one, two or more pixels.

For example, as shown in FIG. 3 and FIG. 4, the number of sub-pixels 200 located in the second region 102 is greater than the number of sub-pixels 200 located in the first region 101. For example, the number of sub-pixels 200 included in different annular sub-regions may be different. For example, the number of rings of the sub-pixels 200 included in different annular sub-regions may be the same or different.

For example, as shown in FIG. 3, the shape of the display surface 1001 may be rectangular, and the shape of the first region 101 may be rectangular, such as a square. For example, the shape of the outline of each annular sub-region may be rectangular, such as a square.

In some examples, as shown in FIG. 1 to FIG. 4, the lens surface 201 of the lens structure 20, such as the curved surface 201, is closer to the display panel 10 at the center than at the edge, and in the direction from the center of the display panel 10 to the edge, the T values of the plurality of sub-pixels 200 in the second region 102 gradually increase, such as having tendency to gradually increase. The gradual increasing tendency may include that the T values of any two adjacent sub-pixels 200 are different and show a tendency to gradually increase in the direction from the center to the edge of the display panel 10. It may also include that in the direction from the center to the edge of the display panel 10, T values of the sub-pixels 200 in two adjacent annular sub-regions are different and show a tendency to gradually increase, but the T values of the sub-pixels 200 in the same annular sub-region are the same.

In some examples, as shown in FIG. 1 to FIG. 4, T values of the sub-pixels 200 in different annular sub-regions increase gradually from the center to the edge of the display panel 10. For example, the farther away from the sub-pixels 200 in the annular sub-region of the first region 101, the greater the deflection angles T of the chief rays of the sub-pixels 200.

For example, as shown in FIG. 4, the lens surface 201 of the lens structure 20, such as the curved surface 201, may be spherical, the heights and the deflection angles of the chief rays of the sub-pixels 200 in the same annular sub-region may be symmetrically distributed with respect to the optical axis of the lens structure 20. Of course, the embodiments of the present disclosure are not limited to this. When the curved surface 201 of the lens structure 20 is an aspherical or free-form surface, the heights and the deflection angles of the chief rays of the sub-pixels 200 in the same annular sub-region need to be set according to the distance between the sub-pixels 200 and the curved surface 201.

FIG. 5 is a schematic diagram of sub-pixels of a local region of the display panel of the display apparatus shown in FIG. 1. FIG. 5 schematically shows that T values and H values of two adjacent sub-pixels 200 are different, but not limited thereto, and the two adjacent sub-pixels 200 shown in FIG. 5 may also represent the sub-pixels 200 in the two adjacent annular sub-regions.

In some examples, as shown in FIG. 1 and FIG. 5, the lens surface 201, such as the curved surface 201, is closer to the display panel 10 at the center than at the edge, and in the direction from the center to the edge of the display panel 10, H values of the plurality of sub-pixels 200 in the second region 102 gradually increase, such as having tendency to gradually increase. The gradual increasing tendency may include that the H values of any two adjacent sub-pixels 200 are different and show a tendency to gradually increase in the direction from the center to the edge of the display panel 10. It may also include that in the direction from the center to the edge of the display panel 10, H values of the sub-pixels 200 in two adjacent annular sub-regions are different and show a tendency to gradually increase, but the H values of the sub-pixels 200 in the same annular sub-region are the same.

In some examples, each sub-pixel 200 represents the sub-pixel 200 in one annular sub-region as shown in FIG. 5, and in the direction from the center to the edge, the T values of the sub-pixels 200 in different annular sub-regions gradually increase and H values of the sub-pixels 200 in different annular sub-regions gradually increase. For example, H3 is greater than H2 and H2 is greater than H1. For example, T3 is greater than T2 and T2 is greater than T1.

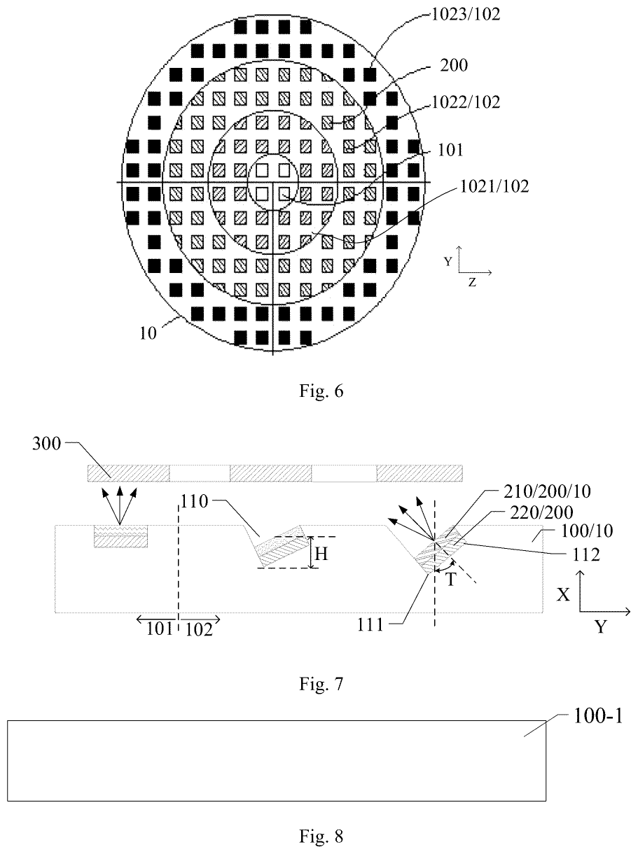

FIG. 6 is a schematic diagram of a partial plane structure of the display panel shown in FIG. 1 in another example. For example, the difference between the display panel shown in FIG. 6 and the display panel shown in FIG. 3 is the arrangement shape of the sub-pixels 200. For example, as shown in FIG. 6, the sub-pixels 200 may be arranged as a circle. For example, the display surface of display panel 10 may be circular. For example, the shape of the first region 101 may be circular. For example, the shape of the second region 102 is in the form of a circular ring. For example, shapes of the annular sub-regions 1021, 1022, and 1023 included in the second region 102 may be in the form of a circular ring.

FIG. 7 is a schematic diagram of a part cross-sectional structure of the display apparatus provided in an example according to an embodiment of the present disclosure.

For example, as shown in FIG. 7, a color film layer 300 is also provided on the light-emitting side of the sub-pixel 200. For example, the color film layer 300 may include a red color film, a green color film and a blue color film. For example, a black shading structure may be provided between different color films. For example, each sub-pixel 200 may be a sub-pixel 200 emitting white light, the white light is converted into red light after passing through the red color film, the white light is converted into green light after passing through the green color film, and the white light is converted into blue light after passing through the blue color film. For example, the plurality of sub-pixels 200 may include a blue sub-pixel emitting blue light, a green sub-pixel emitting green light and a red sub-pixel emitting red light. The light-emitting side of the blue sub-pixel is provided with a blue color film, the light-emitting side of the green sub-pixel is provided with a green color film, the light-emitting side of the red sub-pixel is provided with a red color film. The crosstalk between the light emitted from the sub-pixels 200 of different colors may be reduced by providing the color film layer 300.

For example, as shown in FIG. 1, the lens structure 20 may be a structure in the catadioptric optical path (Pancake). For example, when the lens structure 20 is a single lens, the two surfaces of the lens are respectively provided with a transflective film and a reflective polarizing film, the transflective film is located on one side of the lens close to the display panel 10, the reflective polarizing film is located at the side of the lens away from the display panel 10. A phase retardation film is provided between the transflective film and the reflective polarizing film, and a linear polarizing film is provided on the side that the reflective polarizing film away from the display panel 10. The principle of folding optical path is as follows: the light-emitting side of the display panel 10 may be provided with a wave plate, and the image light emitted from the display panel 10 is converted into right-handed circularly polarized light after passing through the wave plate, and the right-handed circularly polarized light is unchanged after being transmitted by the transflective film. The right-handed circularly polarized light reaches the phase retardation film, and the right-handed circularly polarized light incident on the phase retardation film is converted into p-line polarized light, and the p-line polarized light is reflected back to the phase retardation film by the reflective polarization layer, where the first reflection occurs. Then, the p-line polarized light is converted into the right-handed circularly polarized light after passing through the phase retardation film, and the right-handed circularly polarized light reaches the transflective film and is reflected by the transflective film, where the second reflection occurs. The reflected light changes from right-handed circularly polarized light to left-handed circularly polarized light. The left-handed circularly polarized light is converted into s-line polarized light through the phase retardation film, and then the s-line polarized light is transmitted to a human eye through the reflective polarization layer and the linear polarization film. Of course, the embodiments of the present disclosure are not limited to that the lens structure 20 is a single lens, where the lens structure may also include double lenses, three lenses, four lenses and other structures, which can be set according to the product requirements.

FIG. 8 to FIG. 10 are partial process flow charts of a manufacturing method of a display panel in a display device provided according to an embodiment of the present disclosure.

Another embodiment of the present disclosure provides a method for manufacturing the display apparatus above, including forming the display panel 10 as shown in FIG. 1 and providing the lens structure 20 on the light-emitting side of the display panel 10. The display panel 10 includes the substrate 100 and the plurality of sub-pixels 200 located on the substrate 100, the display panel 10 includes the first region 101 and the second region 102 surrounding the first region 101, and the surface of the lens structure 20 close to the display panel 10 is a curved surface 201. Forming the display panel 10 includes: forming a plurality of inclined grooves 110 on one side of the substrate 100 in the second region 102 facing the lens structure 20; forming the sub-pixel 200 in the inclined groove 110 such that the included angle of the light-emitting surface of the sub-pixels 200 located in the first region 101 relative to the optical axis of the lens structure 20 is greater than the included angle of the light-emitting surface of the sub-pixels 200 located in the second region 102 relative to the optical axis.

For example, as shown in FIG. 8, a substrate material layer 100-1 is provided. For example, the substrate material layer 100-1 may be a base substrate or other film layers disposed on the substrate, such as an insulating layer.

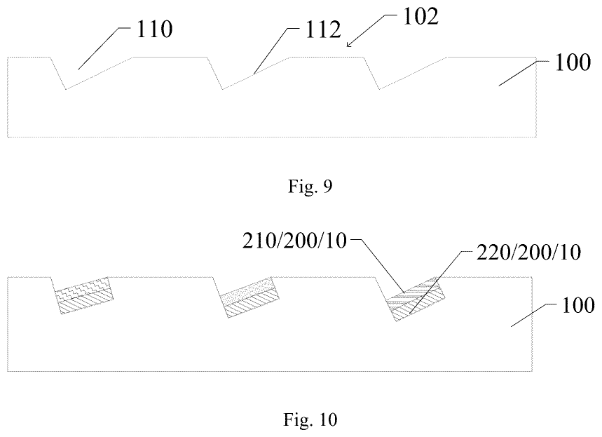

For example, as shown in FIG. 9, a mask is applied to the substrate material layer and exposure and etching are performed to form the inclined groove 110 in the second region 102. For example, the inclined groove 110 includes an inclined main surface 112. For example, when the first region 101 is provided with a groove, the groove in the first region 101 may be formed in the same patterning process as the inclined groove 110 in the second region 102.

For example, as shown in FIG. 10, an electrode layer 220 and a light-emitting layer 210 of the sub-pixels 200 are successively patterned and formed on the substrate 100 with the inclined grooves 110. For example, the electrode layer 220 and the light-emitting layer 210 of the sub-pixels 200 are formed on the inclined main surfaces 112 of the inclined grooves 110. The present disclosure does not show the steps after the forming the light-emitting layer 210, and may be manufactured with reference to the existing process.

In the display apparatus with an inclined groove made by the manufacturing method provided in the embodiments of the present disclosure, by designing the inclination angle of the inclined main surface in the inclined groove, the inclination angle of the light-emitting layer in the sub-pixels formed in the inclined groove may be adjusted, and the included angles of the light-emitting surfaces of the sub-pixels in different regions of the display panel relative to the optical axis of the lens structure may be further adjusted, such that the chief ray angle of the sub-pixels in the display panel may be matched with the chief ray angle of the lens structure.

The following statements should be noted:
(1) In the accompanying drawings of the embodiments of the present disclosure, the drawings involve only the structure(s) in connection with the embodiment(s) of the present disclosure, and other structure(s) can be referred to common design(s).
(2) In case of no conflict, features in one embodiment or in different embodiments can be combined. What have been described above are only specific implementations of the present disclosure, the protection scope of the present disclosure is not limited thereto, and the protection scope of the present disclosure should be based on the protection scope of the claims.

1. A display apparatus, comprising:
a display panel comprising a substrate and a plurality of sub-pixels located on the substrate;
a lens structure located on a light-emitting side of the display panel, and a lens surface of the lens structure close to the display panel being a curved surface,
wherein the display panel comprises a first region and a second region surrounding the first region, and an included angle between a light-emitting surface of a sub-pixel located in the first region and an optical axis of the lens structure is greater than an included angle between a light-emitting surface of a sub-pixel located in the second region and the optical axis.

2. The display apparatus according to claim 1, wherein a chief ray of the sub-pixel located in the first region is parallel to the optical axis of the lens structure, and an included angle between a chief ray of the sub-pixel located in the second region and the optical axis is greater than 0 degrees and less than or equal to 75 degrees.

3. The display apparatus according to claim 2, wherein the substrate comprises a reference surface, and a distance between a center of the light-emitting surface of the sub-pixel in the first region and the reference surface is smaller than a distance between a center of the light-emitting surface of the sub-pixel in the second region and the reference surface.

4. The display apparatus according to claim 1, wherein minimum distances between the lens surface and centers of the light-emitting surfaces of the sub-pixels are 0.2 mm to 50 mm.

5. The display apparatus according to claim 1, wherein a radius of curvature of the lens surface is −300 mm to 300 mm.

6. The display apparatus according to claim 1, wherein a part of the substrate located in the second region is provided with an inclined groove, the inclined groove comprises a groove bottom furthest away from the lens structure, and a distance between a center of the light-emitting surface of the sub-pixel located in the inclined groove and a plane parallel to a main surface of the substrate where the groove bottom is located is 20 nm to 50 mm.

7. The display apparatus according to claim 1, wherein a chief ray angle CRA1 of at least some sub-pixels in the display panel and a chief ray angle CRA0 of the lens structure satisfy a following relationship:
$$CRA 1 = \{ [ {tan}^{- 1} ( H - Z ) ] / ( f + e + T + CRA 0 ) \} + \{ [ {tan}^{- 1} ( H / Z ) ] / ( R - f - e - T - CRA 0 ) \} ,$$
where a part of the substrate located in the second region is provided with an inclined groove, the inclined groove comprises a groove bottom furthest away from the lens structure, a distance between a center of the light-emitting surface of the sub-pixel located in the inclined groove and a plane parallel to a main surface of the substrate where the groove bottom is located is H, a distance between the lens surface and a display surface at a position of the sub-pixel is Z, f represents a focal length of the lens structure, e represents a size of an entrance pupil, T represents an included angle between the chief ray angle of the sub-pixel and the optical axis of the lens structure, and R represents a radius of curvature of the lens surface.

8. The display apparatus according to claim 7, wherein the lens surface is closer to the display panel at a center than at an edge, and in a direction from a center to an edge of the display panel, T values of multiple sub-pixels in the second region gradually increase.

9. The display apparatus according to claim 7, wherein the lens surface is closer to the display panel at a center than at an edge, and in a direction from a center to an edge of the display panel, H values of multiple sub-pixels in the second region gradually increase.

10. The display apparatus according to claim 7, wherein the second region comprises a plurality of annular sub-regions, the first region comprises a center of the display panel, and the plurality of annular sub-regions is provided sequentially along a direction from the center to the edge, and for different sub-pixels in the same annular sub-region, T values are the same, and H values are the same.

11. The display apparatus according to claim 10, wherein, in the direction from the center to the edge, for the sub-pixels in different annular sub-regions, T values gradually increase, and H values gradually increase.

12. The display apparatus according to claim 1, wherein an incident angle of a chief ray of light emitted from the light-emitting surface of the sub-pixel in the second region that is incident on the lens surface is not greater than 5 degrees.

13. The display apparatus according to claim 1, wherein the plurality of sub-pixels comprises a red sub-pixel, a green sub-pixel, and a blue sub-pixel.

14. The display apparatus according to claim 1, wherein the lens surface comprises a spherical surface, an aspherical surface, or a freeform curved surface.

15. The display apparatus according to claim 1, wherein each sub-pixel comprises a light-emitting diode or an organic light-emitting diode.

16. The display apparatus according to claim 6, wherein the inclined groove comprises an inclined main surface, the sub-pixel comprises a light-emitting layer, and the light-emitting layer is arranged on the inclined main surface.

17. The display apparatus according to claim 2, wherein a part of the substrate located in the second region is provided with an inclined groove, the inclined groove comprises a groove bottom furthest away from the lens structure, and a distance between a center of the light-emitting surface of the sub-pixel located in the inclined groove and a plane parallel to a main surface of the substrate where the groove bottom is located is 20 nm to 50 mm.

18. The display apparatus according to claim 3, wherein a part of the substrate located in the second region is provided with an inclined groove, the inclined groove comprises a groove bottom furthest away from the lens structure, and a distance between a center of the light-emitting surface of the sub-pixel located in the inclined groove and a plane parallel to a main surface of the substrate where the groove bottom is located is 20 nm to 50 mm.

19. The display apparatus according to claim 2, wherein a chief ray angle CRA1 of at least some sub-pixels in the display panel and a chief ray angle CRA0 of the lens structure satisfy a following relationship:
$$CRA 1 = \{ [ {tan}^{- 1} ( H - Z ) ] / ( f + e + T + CRA 0 ) \} + \{ [ {tan}^{- 1} ( H / Z ) ] / ( R - f - e - T - CRA 0 ) \} ,$$
where a part of the substrate located in the second region is provided with an inclined groove, the inclined groove comprises a groove bottom furthest away from the lens structure, a distance between a center of the light-emitting surface of the sub-pixel located in the inclined groove and a plane parallel to a main surface of the substrate where the groove bottom is located is H, a distance between the lens surface and a display surface at a position of the sub-pixel is Z, f represents a focal length of the lens structure, e represents a size of an entrance pupil, T represents an included angle between the chief ray angle of the sub-pixel and the optical axis of the lens structure, and R represents a radius of curvature of the lens surface.

20. A method for manufacturing a display apparatus, comprising:
forming a display panel, wherein the display panel comprises a substrate and a plurality of sub-pixels located on the substrate;
providing a lens structure on a light-emitting side of the display panel, wherein a lens surface of the lens structure close to the display panel is a curved surface,
wherein the display panel comprises a first region and a second region surrounding the first region, and forming the display panel comprises:
forming a plurality of inclined grooves on a side of the substrate in the second region facing the lens structure; and
forming the sub-pixels in the inclined grooves such that an included angle between a light-emitting surface of a sub-pixel located in the first region and an optical axis of the lens structure is greater than an included angle between a light-emitting surface of a sub-pixel located in the second region and the optical axis.
